(19) United States
(12) Patent Application Publication
(10) Pub. No.: US 2025/0364782 A1
(43) Pub. Date: Nov. 27, 2025

(54) LASER MODULE, CONTROL METHOD FOR LASER MODULE AND CONTROL DEVICE

(71) Applicant: Nippon Telegraph and Telephone Corporation, Tokyo (JP)

(72) Inventors: Hayato Arai, Tokyo (JP); Wataru Kobayashi, Tokyo (JP); Manabu Mitsuhara, Tokyo (JP)

(21) Appl. No.: 18/868,016

(22) PCT Filed: May 24, 2022
(86) PCT No.: PCT/JP2022/021213

§ 371 Date: Nov. 21, 2024

(51) Int. Cl. H01S 5/062; H01S 5/00; H01S 5/042; H01S 5/323

(52) U.S. Cl. CPC H01S 5/06236; H01S 5/005; H01S 5/04256; H01S 5/323

(57) ABSTRACT

A laser module of includes a semiconductor laser which oscillates with either one of clockwise circularly polarized light and counterclockwise circularly polarized light; and a quarter-wave retarder disposed on an emission surface side of the semiconductor laser, wherein the semiconductor laser is driven by a current which is higher than a threshold current of the one circularly polarized light and lower than a threshold current of the other circularly polarized light. A semiconductor laser includes an n-type clad layer, an active layer, and a p-type clad layer. Further, the laser module includes an n-type electrode and a p-type electrode, and at least one of the n-type electrode and the p-type electrode is a ferromagnetic electrode.

### CROSS-REFERENCE TO RELATED APPLICATIONS

This application is a national phase entry of PCT Application No. PCT/JP2022/021213, filed on May 24, 2022, which application is hereby incorporated herein by reference.

### TECHNICAL FIELD

The present invention relates to a laser module capable of suppressing the influence of returned light, and a method and an apparatus for controlling the laser module.

### BACKGROUND

Semiconductor lasers are widely utilized in the field of optical communication. In an optical communication system, a laser beam of a semiconductor laser enters (couples) an optical fiber and propagates in the optical fiber as signal light.

In some cases, the laser beam of the semiconductor laser is reflected by the end face of the optical fiber or the like, and is again incident on the semiconductor laser as returned light. The returned light is amplified by induced emission even if the intensity of the returned light is smaller than that of the emitted light, and causes noise and mode instability.

In order to prevent the influence of the returned light, an optical isolator in which a linear polarizer and a Faraday rotator are combined is used (for example, PTL 1). The optical isolator can set the returned light to a TM mode by rotating the light emitted from the laser oscillating in a TE mode by 45 degrees in a forward path and a backward path, respectively. Since the returned light in the TM mode is absorbed by the linear polarizer in the optical isolator, noise and mode instability due to the returned light are suppressed.

### CITATION LIST

### Patent Literature

PTL 1-Japanese Patent Application Publication No. 2005-099503

### SUMMARY

### Technical Problem

However, the Faraday rotator used in the optical isolator has a high price, which causes a problem in cost reduction. Since an expensive material such as yttrium iron garnet (YIG) is used for the Faraday rotator, it is difficult to reduce the cost through device design.

### Solution to Problem

In order to solve the above problem, a laser module according to embodiments of the present invention includes a semiconductor laser which oscillates with either one of clockwise circularly polarized light and counterclockwise circularly polarized light; and a quarter-wave retarder disposed on an emission surface side of the semiconductor laser, wherein the semiconductor laser is driven by a current which is higher than a threshold current of the one circularly polarized light and lower than a threshold current of the other circularly polarized light.

A method for controlling a laser module according to embodiments of the present invention is a method for controlling a laser module which includes a semiconductor laser that oscillates with either one of clockwise circularly polarized light and counterclockwise circularly polarized light, and a quarter-wave retarder disposed on an emission surface side of the semiconductor laser, the method including injecting a current higher than a threshold current of the one circularly polarized light and lower than a threshold current of the other circularly polarized light into the semiconductor laser.

A control apparatus of the laser module according to embodiments of the present invention is an apparatus for controlling a laser module which includes a semiconductor laser that oscillates with either one of clockwise circularly polarized light and counterclockwise circularly polarized light, and a quarter-wave retarder disposed on an emission surface side of the semiconductor laser, in which a current higher than a threshold current of the one circularly polarized light and lower than a threshold current of the other circularly polarized light is injected into the semiconductor.

### Advantageous Effects

According to embodiments of the present invention, it is possible to provide an inexpensive laser module capable of suppressing the influence of returned light, and a method and an apparatus for controlling the laser module.

### BRIEF DESCRIPTION OF THE DRAWINGS

FIG. 1 is a schematic diagram showing the configuration of a laser module according to a first embodiment of the present invention.

FIG. 2 is a diagram for explaining the operation of the laser module according to the first embodiment of the present invention.

FIG. 3 is a diagram for explaining the operation of the laser module according to the first embodiment of the present invention.

FIG. 4 is a flowchart for explaining a method of controlling the laser module according to the first embodiment of the present invention.

FIG. 5A is a diagram for explaining the effect of the laser module according to the first embodiment of the present invention.

FIG. 5B is a diagram for explaining the effect of the laser module according to the first embodiment of the present invention.

FIG. 6A is a diagram for explaining the effect of the laser module according to the first embodiment of the present invention.

FIG. 6B is a diagram for explaining the effect of the laser module according to the first embodiment of the present invention.

FIG. 7 is a schematic diagram showing the configuration of the laser module according to the first embodiment of the present invention.

FIG. 8 is a schematic diagram showing a configuration of a laser module according to a second embodiment of the present invention.

FIG. 9 is a schematic diagram showing a configuration of a laser module according to a third embodiment of the present invention.

FIG. 10 is a diagram showing a configuration example of a computer in an embodiment of the present invention.

### DETAILED DESCRIPTION OF ILLUSTRATIVE EMBODIMENTS

### First Embodiment

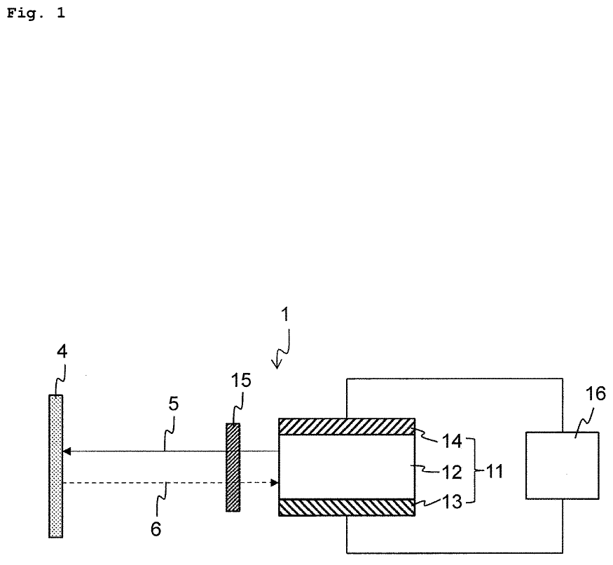

A laser module according to a first embodiment of the present invention will be described with reference to FIGS. 1 to 6B.

### Configuration of Laser Module

As shown in FIG. 1, a laser module 1 according to the present embodiment includes a semiconductor laser 11 and a quarter-wave retarder 15.

An emitted light 5 of the semiconductor laser 11 is reflected by an external reflecting mirror 4 and made incident on the semiconductor laser 11 as a returned light 6. Here, the reflection by the external reflecting mirror 4 corresponds to, for example, the reflection by an end face of the optical fiber or various optical components in an ordinary optical communication.

A control device 16 supplies a current to the semiconductor laser 11.

The semiconductor laser 11 is a spin laser, and includes a semiconductor layer structure 12, a p-type electrode 13, and an n-type electrode 14.

In the semiconductor laser 11, either one of the p-type electrode 13 and the n-type electrode 14 is a ferromagnetic electrode. A ferromagnetic material magnetized in the same direction as an emitting direction of light is used as a material of the ferromagnetic material electrode. Here, both electrodes may be ferromagnetic electrodes.

The light 5 to be emitted from the semiconductor laser 11 passes through the quarter-wave retarder 15. The light reflected by the external reflecting mirror 4 (e.g., an optical fiber end face, various optical components, etc.) passes through the quarter-wave retarder 15 as the returned light 6 and enters the semiconductor laser 11.

### Basic Operation of Semiconductor Laser

The basic operation of the semiconductor laser (spin laser) 11 of the present embodiment will be explained below.

In the spin laser 11, a phenomenon in which a spin (upward/downward) of electrons corresponds to a direction (clockwise/counterclockwise) of circularly polarized light emitted by recombination is used. That is, by injecting a spin-polarized current into the semiconductor laser 11, circularly polarized light is emitted from the active layer in the semiconductor layer structure 12.

The spin laser 11 is superior to a conventional semiconductor laser in that a threshold current can be reduced (M. Holub, et al., “Electrical Spin Injection and Threshold Reduction in a Semiconductor Laser,” Physical Review Letters, 98, 146603 (2007)).

The reduction of the threshold current is caused by a phenomenon that only circularly polarized light in either a clockwise or counterclockwise direction can be laser-oscillated by controlling the direction of the spin injected into the laser. That is, when the injection current to the semiconductor laser is increased, only the circularly polarized light in the direction corresponding to the spin of the majority is dominantly laser oscillated by a low current, and the circularly polarized light corresponding to the spin of the minority does not oscillate the laser, but only the light is emitted by spontaneous emission.

When the current injected into the spin laser 11 is defined as I and the spin polarization of the injected current is defined as P, a current I₊ having a large number of spins and a current I₋ having a minor spin can be respectively described by equation (1).

$$Equation 1$$

$${I}_{+} = \frac{1 + \vert P \vert}{2} I \qquad ( 1 )$$

$${I}_{-} = \frac{1 - \vert P \vert}{2} I$$

When the relaxation of the spin is not considered, assuming that the threshold current at the time of injecting current without spin polarization is Iₜₕ, the threshold current Iₜₕ₁ of lasing by the charge of the majority spin and the threshold current Iₜₕ₂ of lasing by the charge of the minority spin can be described by equation (2), respectively.

$$Equation 2$$

$${I}_{th 1} = \frac{1}{1 + \vert P \vert} {I}_{th} \qquad ( 2 )$$

$${I}_{th 2} = \frac{1}{1 - \vert P \vert} {I}_{th}$$

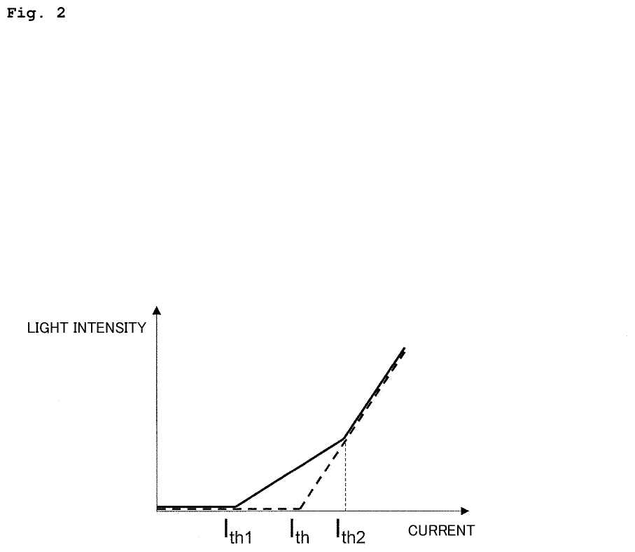

The light intensity-current characteristics at this time are shown in FIG. 2.

For example, if |P|>0, Iₜₕ₁<Iₜₕ is established, the threshold current of the spin laser 11 is reduced as compared with a conventional laser. At this time, only the circularly polarized light in one direction lases in a region in which the injection current is in the range of Iₜₕ₁<I<Iₜₕ₂.

A degree of circular polarization of the light P_{C} is a parameter represents the purity of circularly polarized light, and P_{C}=(S₊−S₋)/(S₊+S₋) is established. Here, S₊ and S₋ are circularly polarized light intensities in clockwise and counterclockwise direction, respectively.

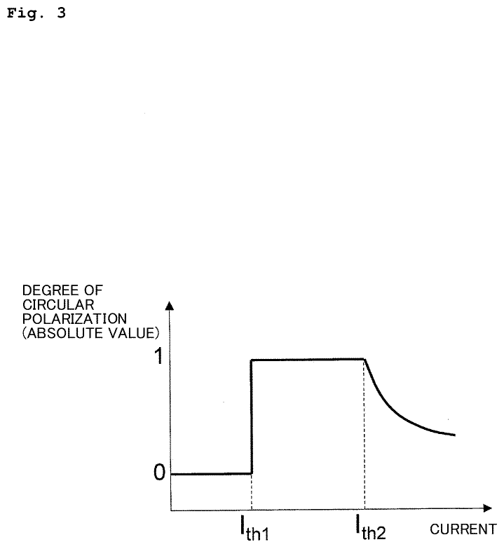

FIG. 3 shows the injection current dependence of the degree of circular polarization of light P_{C}. In a state in which only the one (clockwise or counterclockwise) circularly polarized light is lasing, the degree of circular polarization is about 1, and a pure one (clockwise or counterclockwise) circularly polarized laser beam is obtained.

In a state in which the injection current is increased and both circularly polarized lights are lasing, the degree of circular polarization gradually approaches 0.5.

### Method of Controlling Laser Module

A method of controlling the laser module 1 according to the present embodiment will be described below. The method of controlling the laser module 1 according to the present embodiment is executed by the control device 16.

In the laser module 1 according to the present embodiment, when spin polarization in a ferromagnetic electrode is defined as P, and threshold current with ferromagnetic material not magnetized is defined as Iₜₕ, a value of the current I injected into the semiconductor laser 11 is driven within a range of Iₜₕ/(1+/P|)<I<Iₜₕ/(1−P|).

Since the electrons in the magnetized ferromagnetic material have spin polarization, the current injected from the ferromagnetic material into the active layer of the semiconductor laser 11 also has spin polarization. Therefore, there is also a difference in intensity of the circularly polarized light (clockwise/counterclockwise) to be emitted.

When the spin relaxation is not taken into consideration as described above, since the value of the injected current I is driven in the range of Iₜₕ/(1+|P|)<I<Iₜₕ/(1−| P|), only the circularly polarized light by the majority carrier is lasing, and the minority carrier is in a state in which it hardly contributes to induced emission.

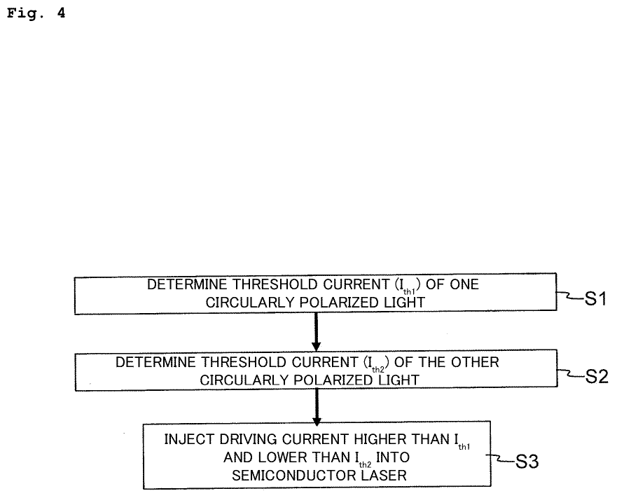

FIG. 4 is a flowchart diagram of a control method of the laser module 1.

First, a threshold current (Iₜₕ₁) of one circularly polarized light is determined (step S1). Iₜₕ₁ is acquired by driving and measuring the semiconductor laser 11 in advance, and stored in a storage unit of the control device 16.

Next, the threshold current (Iₜₕ₂) of the other circularly polarized light is determined (step S2). Iₜₕ₂ is acquired by driving and measuring the semiconductor laser 11 in advance, and stored in the storage unit of the control device 16.

Finally, a driving current higher than Iₜₕ₁ and lower than Iₜₕ₂ is injected into the semiconductor laser 11 on the basis of the stored Iₜₕ₁ and Iₜₕ₂ (step S3).

### Effects

Effects of the laser module 1 according to the present embodiment will be described below.

In a normal laser module, an optical isolator in which a linear polarizer and a Faraday rotator are combined is used, linearly polarized light in a TE mode is transmitted, rotated by 45° by the Faraday rotator, further rotated by 45° with respect to the returned light, and rotated by 90° together.

As a result, because the returned light enters the TM mode and is absorbed by the linear polarizer in the optical isolator, the returned light does not enter the laser. Therefore, noise and mode instability due to returned light are suppressed.

As described above, in an ordinary laser module, a Faraday rotator is required to rotate the linearly polarized light.

In the laser module 1 according to the present embodiment, the semiconductor laser 11 lases emitting the circularly polarized light. Further, the semiconductor laser 11 is driven in the range of Iₜₕ/(1+|P|)<I<Iₜₕ/(1−|P|), and lases in either clockwise or counterclockwise circularly polarized light (e.g., clockwise).

With respect to the circularly polarized laser beam of one direction (e.g., clockwise), the returned light 6 is transmitted twice through the quarter-wave retarder 15 disposed in the emission direction by the structure shown in FIG. 1. The transmission through the quarter-wave retarder 15 twice is equivalent to the transmission through the half-wave plate, and the direction of the circularly polarized light transmitted through the half-wave plate is reversed. For example, when the clockwise circularly polarized light is lasing, the returned light 6 turns counterclockwise.

As a result, since the semiconductor laser 11 does not lase in the counterclockwise circularly polarized light, the returned light 6 is not amplified by induced emission. Therefore, in the laser module 1, noise due to the returned light 6 can be suppressed.

As described above, in the laser module according to the present embodiment, by the configuration of the semiconductor laser lasing in circularly polarized light and the quarter-wave retarder, it is possible to suppress noise due to returned light without using a Faraday rotator.

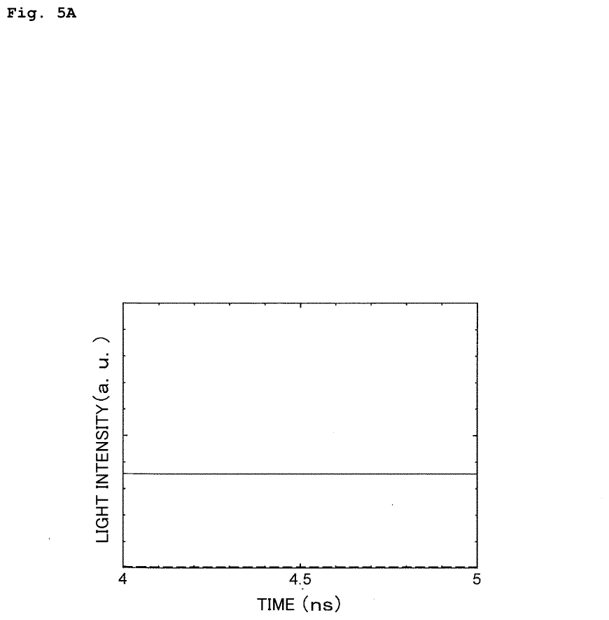

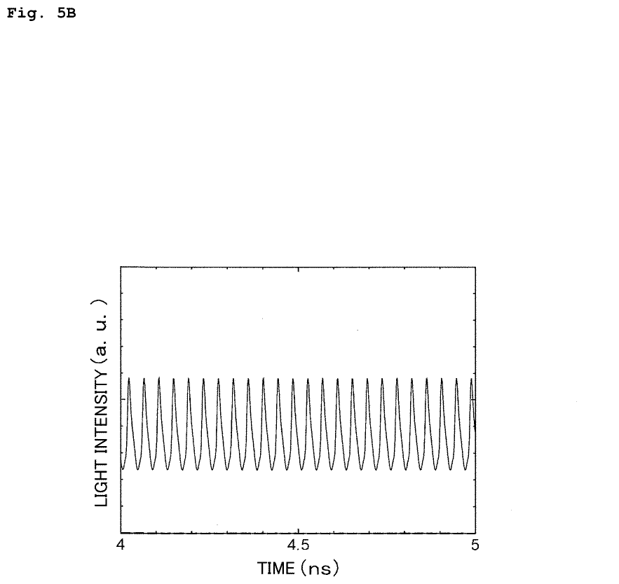

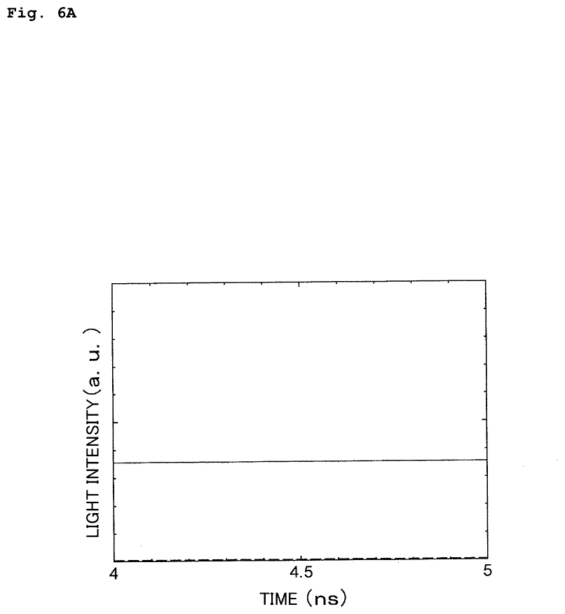

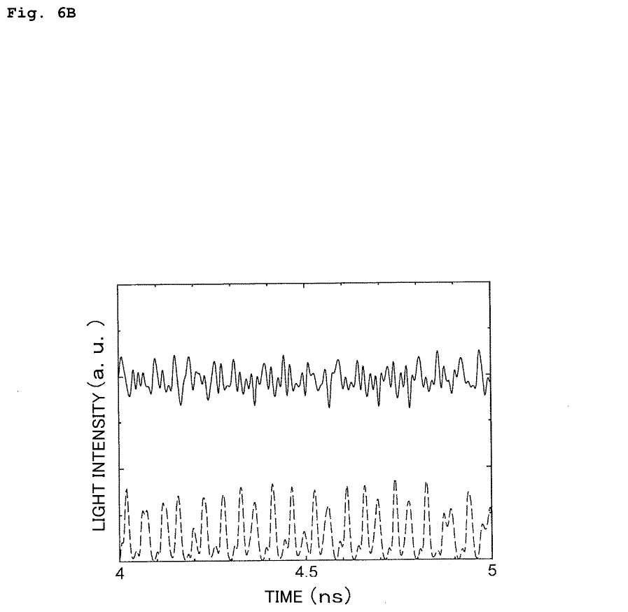

The effects of the laser module 1 according to the present embodiment will be explained with reference to the calculation results of dynamic characteristics shown in FIGS. 5A to 6B.

The dynamic characteristics of the light intensity of the laser module 1 according to the present embodiment are calculated by equations (3) and (4). Table 1 shows constants (parameters) in equations (3) and (4).

$$Equation 3$$

$$\frac{\partial {N}_{\pm }}{\partial t} = \frac{{I}_{\pm }}{e V} − ( \frac{{v}_{g} {A}_{g} ( {N}_{\pm } − {N}_{t} )}{1 + ϵ {\vert {E}_{∓} \vert}^{2}} ) {\vert {E}_{∓} \vert}^{2} − \frac{{N}_{\pm } − {N}_{∓}}{{τ}_{s}} − \frac{{N}_{\pm }}{{τ}_{c}} \qquad ( 3 )$$

$$Equation 4$$

$$\frac{\partial {E}_{\pm }}{\partial r} = \frac{1}{2} ( 1 + i α ) ( Γ {v}_{g} {A}_{g} \frac{( {N}_{∓} − {N}_{t} )}{1 + ϵ {\vert {E}_{\pm } \vert}^{2}} − \frac{1}{{τ}_{p}} ) {E}_{\pm } + \sqrt{\frac{Γ β {N}_{∓}}{{τ}_{c}}} + κ {E}_{∓} ( t - τ ) exp ( - i Ωτ ) \qquad ( 4 )$$

TABLE 1

| Expression: | Constant (parameter) | Value | Unit |
|---|---|---|---|
| e | Elementary charge | 1.6 × 10⁻¹⁹ | C |
| V | Active layer volume | 5.0 × 10⁻¹⁸ | m³ |
| ν_{g} | Group velocity | 9.0 × 10⁷ | m/s |
| A_{g} | Differential gain coefficient | 1.2 × 10⁻¹⁸ | m² |
| Nₜ | Transparent carrier concentration | 3.8 × 10²⁴ | 1/m³ |
| ϵ | Gain saturation coefficient | 1.5 × 10⁻²³ | m³ |
| τₛ | Spin relaxation time | 20 | ps |
| τ_{c} | Recombination lifetime | 1.0 | ns |
| τₚ | Photon relaxation time | 1.5 | ps |
| α | Line width increasing coefficient | 5.0 | — |
| Γ | Confinement factor | 0.1 | — |
| β | Natural emission coefficient | 1.0 × 10⁻⁴ | — |
| κ | Returned light intensity parameter | 3.0 × 10¹⁰ | 1/s |
| τ | Navigation time of returned light | 3.33 × 10⁻¹¹ | s |
| Ω | Angular frequency of returned light | 1.21 × 10¹⁶ | rad/s |

Equations (3) and (4) are rate equations in consideration of the direction of the spin of electrons, the circularly polarized light, and the returned light, with respect to an electron density N± of the upward spin and the downward spin, and an electric field E± of the clockwise and counterclockwise circularly polarized light, respectively. Here, + represents upward spin and clockwise circularly polarized light, and − represents downward spin and counterclockwise circularly polarized light. The returned light is considered as circularly polarized light in the direction opposite to the direction of the emitted light.

In this case, I± is the injection current of the spin, + indicates the upward spin, and − indicates the downward spin.

Equation (4) is an equation in which a third term is added to the rate equation of the spin laser 11 (N. Yokota, et al., “Lasing Polarization Characteristics in 1.55-um Spin-Injected VCSELs,” IEEE PHOTONICS TECHNOLOGY LETTERS, 29(9), 711(2017).), as a term indicating the influence of returned light (birefringence and circularly polarized light dichroism are ignored).

Further, in a case where the quarter-wave retarder 15 is provided, it is expressed by adding the contribution of the counterclockwise or clockwise returned light to the equation of the clockwise or counterclockwise circularly polarized light, respectively. That is, the electric field of the circularly polarized light in the third term of the equation (4) is calculated by using E₋

On the other hand, when the quarter-wave retarder 15 is not provided, it is expressed by adding the term of the clockwise or counterclockwise returned light to the expression of the clockwise or counterclockwise circularly polarized light, respectively. That is, the electric field of the circularly polarized light in the third term of the equation (4) is calculated by using E₊.

FIGS. 5A and 5B show the results of calculation of the dynamic characteristics of the light intensity of the laser module 1 in the case where the quarter-wave retarder 15 is provided and in the case where the quarter-wave retarder 15 is not provided. Here, the light intensity |E₊|² of the clockwise circularly polarized light is indicated by a solid line, and the light intensity |E⁻|² of the counterclockwise circularly polarized light is indicated by a dotted line.

Here, the injection current is set to be constant in the range in which only the circularly polarized light in one direction (clockwise) is lasing, that is, Iₜₕ/(1+|P|)<I<Iₜₕ/(1−|P|). Further, the spin polarization is made constant. In this way, one (clockwise) circularly polarized light is predominantly lasing.

When the quarter-wave retarder 15 is not provided, the light intensity |E₊|² greatly fluctuates due to the influence of the returned light, though a constant current is injected, as shown in FIG. 5B. The light intensity |E₋|² is almost o (zero) because the counterclockwise circularly polarized light does not lase.

In this case, because one (clockwise) circularly polarized light emitted from the semiconductor laser 11 is reflected outside and returned to the semiconductor laser 11 in a polarized state as it is, the intensity of one (clockwise) circularly polarized light lasing dominantly is varied.

The variation (fluctuation) of the light intensity deteriorates the stable operation of the semiconductor laser 11. The conventional laser module requires an optical isolator using YIG or the like to suppress the fluctuation of the light intensity and to compensate the stability of the operation of the semiconductor laser.

On the other hand, in the case of having the quarter-wave retarder 15, the fluctuation of the light intensity |E₊|² is very small as shown in FIG. 5A.

In this case, when one (clockwise) circularly polarized light emitted from the semiconductor laser 11 is reflected by the outside and returned to the semiconductor laser 11 through the quarter-wave retarder 15, the one (clockwise) circularly polarized light is inverted and turned counterclockwise, and becomes a polarized state opposite to the one circularly polarized light (clockwise). Accordingly, the intensity of the circularly polarized light of one (clockwise) which lases dominantly is not varied.

Thus, in the laser module 1, the semiconductor laser 11 lasing by one circularly polarized light and the quarter-wave retarder 15 can be combined to suppress the fluctuation of the light intensity.

FIGS. 6A and 6B show the results of calculation of the dynamic characteristics of the light intensity of the laser module 1 having the quarter-wave retarder 15 in the case of driving the injection current to the semiconductor laser 11 to be less than Iₜₕ₂ and in the case of driving the injection current to be the current higher than Iₜₕ₂, respectively.

Here, the dynamic characteristic of the light intensity is calculated with the injection current as the sum of I₊ and I₋ and the ratio of I₊ and I₋ as constant.

When the injection current to the semiconductor laser 11 is driven with a current higher than that of Iₜₕ₂, not only one (clockwise) circularly polarized light is lasing by the majority carrier, but also the other (counterclockwise) circularly polarized light is lasing by the minority carrier, as shown in FIG. 6B, and lasing of both circularly polarized lights is obtained.

Here, the intensity of one (clockwise) circularly polarized light and the intensity of the other (counterclockwise) circularly polarized light are increased, and the intensity of each of the circularly polarized light varies greatly. At this time, the intensity of the circularly polarized light of one (clockwise) is larger than that of the circularly polarized light of the other (counterclockwise), and lasing of the circularly polarized light of one (clockwise) is dominant.

In this case, when the other (counterclockwise) circularly polarized light returns to the semiconductor laser 11 through the quarter-wave retarder 15, the other (counterclockwise) circularly polarized light is inverted and turned clockwise, and becomes the same polarized state as the one circularly polarized light (clockwise). Accordingly, the intensity of the one (clockwise) circularly polarized light which is dominantly lasing is varied.

When one (clockwise) circularly polarized light returns to the semiconductor laser 11 through the quarter-wave retarder 15, one (clockwise) circularly polarized light is inverted and turned counterclockwise, and becomes the same polarized state as the other (counterclockwise) circularly polarized light. Accordingly, the intensity of the other (counterclockwise) circularly polarized light is varied.

Therefore, even in the configuration having the quarter-wave retarder 15, the influence of noise due to the returned light becomes large, and the light intensity fluctuates.

On the other hand, when the injection current of the semiconductor laser 11 is driven to be less than Iₜₕ₂, the fluctuation of the light intensity |E₊|² is very small as shown in FIG. 6A. In this way, in the laser module 1, by driving the injection current to be less than Iₜₕ₂, the fluctuation of the light intensity can be suppressed.

In this way, when the injection current is driven with less than Iₜₕ₂, since the other (counterclockwise) circularly polarized light does not lase, the intensity of the one (clockwise) circularly polarized light which lases dominantly is not varied.

According to the laser module according to the present embodiment, it is possible to stably suppress variation in laser light intensity without using an optical isolator using YIG or the like, and to reduce the cost of the laser module.

In the present embodiment, although an example in which the semiconductor laser (spin laser) is driven at an injection current of less than Iₜₕ₂ and lasing with clockwise circularly polarized light is shown, the same effect can be obtained even when lasing with counterclockwise circularly polarized light.

### First Embodiment

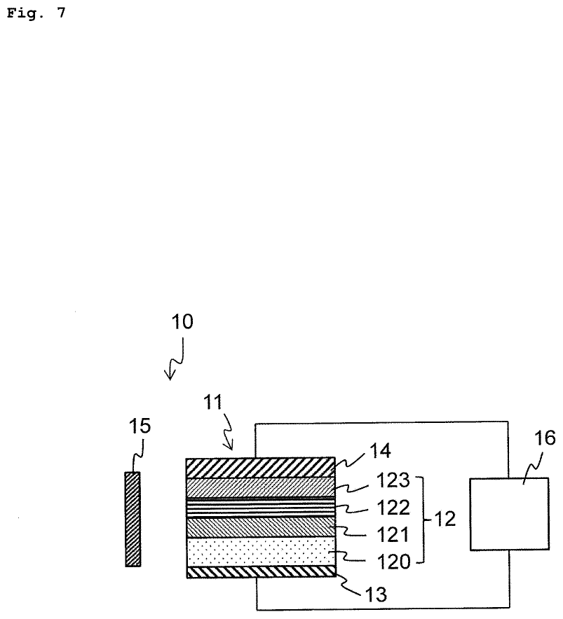

A laser module according to a first embodiment of the present invention will be described with reference to FIG. 7.

As shown in FIG. 7, the laser module according to the present embodiment includes a semiconductor laser 11 and a quarter-wave retarder 15. A control device 16 for driving the semiconductor laser 11 is provided.

The semiconductor laser 11 includes, in order, a p-type GaAs substrate 120, a p-type AlGaAs clad layer 121 (layer thickness: for example, about 1 μm), a GaAs active layer 122 (layer thickness: for example, about 500 nm), and an n-type AlGaAs clad layer 123 (layer thickness: for example, about 1 μm), and the emission wavelength is 850 nm.

A p-type electrode 13 is formed on a rear surface of the p-type GaAs substrate 120. Here, the p-type electrode 13 may be formed to be electrically connected to the p-type AlGaAs clad layer 121. For example, when the p-type AlGaAs clad layer 121 is formed on a semi-insulating GaAs substrate, the p-type electrode 13 may be formed on the p-type AlGaAs clad layer 121.

A laminated metal film of Ti and Au having low electric resistance or a laminated metal film of Ti, Pt and Au is used for the p-type electrode 13. Another metal material capable of obtaining a low electric resistance may be used for the p-type electrode 13. The thickness of the p-type electrode 13 is, for example, about 100 nm to 1 μm.

An n-type electrode 14 is formed on the surface of the n-type AlGaAs clad layer 123. Here, the n-type electrode 14 may be formed to be electrically connected to the n-type AlGaAs clad layer 123.

The n-type electrode 14 uses Fe which is a ferromagnetic material at normal temperature, and is formed by MBE or sputtering or the like. The n-type electrode 14 may be made of an alloy such as Co or CoFeB. The thickness of the n-type electrode 14 is about 100 nm to 1 μm, for example.

When the semiconductor laser 11 of the laser module 10 is driven in a state in which Fe as a ferromagnetic electrode (n-type electrode) 14 is not magnetized, lasing is performed at a threshold current of 10 mA similarly to a conventional semiconductor laser. Further, the light intensity greatly varies due to the influence of the returned light.

On the other hand, when the semiconductor laser 11 of the laser module 10 is driven in a state in which Fe as a ferromagnetic electrode (n-type electrode) 14 is magnetized, since the spin polarization of Fe is about 0.4 (S. V. Karthik, et. al., “Spin polarization of Co—Fe alloys estimated by point contact Andreev reflection and tunneling magnetoresistance,” Applied Physics Letters, 105, 07C916 (2009).), the threshold current Iₜₕ₁ in the circularly polarized light in one direction and the threshold current Iₜₕ₂ in the circularly polarized light in the other direction are Iₜₕ=Iₜₕ/(1+|P|)=7.1 mA, and Iₜₕ2=Iₜₕ/(1−|P|)=16.7 mA, respectively (where spin relaxation is ignored).

Here, a magnetic field (magnetic field intensity: for example, 1 to 10 Tesla) is applied to the laser module 10, Fe (ferromagnetic electrode 14) is magnetized in one direction (for example, corresponding to upward spin) in a direction parallel to the emission direction of the laser beam, and Fe is used as the ferromagnetic electrode of the permanent magnet. Here, Fe (ferromagnetic electrode 14) may be magnetized in a direction opposite to one direction in a direction parallel to the emission direction of the laser beam (for example, corresponding to downward spin).

Therefore, when the semiconductor laser 11 of the laser module 10 was driven at a power higher than Iₜₕ₁ (7.1 mA) and lower than Iₜₕ₂ (16.7 mA), for example, 10 mA, as shown in FIGS. 5A and 6A, good characteristics with very small fluctuations in light intensity can be obtained.

According to the laser module according to the present embodiment, it is possible to stably suppress variation in laser light intensity without using an optical isolator using YIG or the like, and to reduce the cost of the laser module.

### Second Embodiment

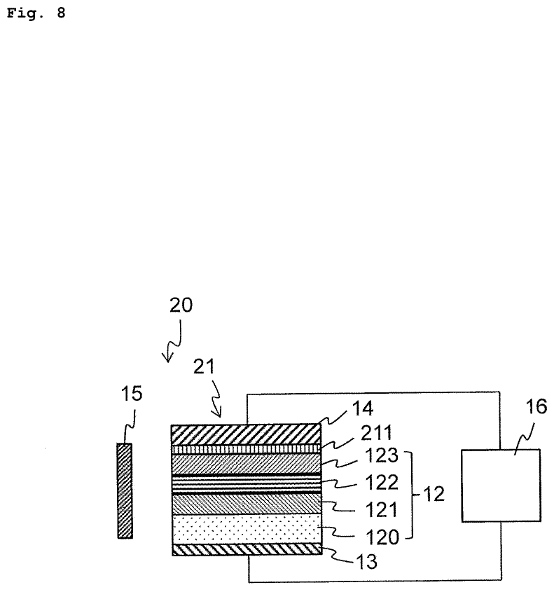

A laser module according to a second embodiment of the present invention will be described with reference to FIG. 8.

As shown in FIG. 8, a semiconductor laser 21 in a laser module 20 according to the present embodiment has an insulating tunnel layer 211 between an n-type clad layer 123 and a ferromagnetic electrode (n-type electrode) 14. The other components are the same as those of the first embodiment.

The insulating tunnel layer 211 is made of MgO as an insulator, and is formed by MBE or sputtering. The thickness of the insulating tunnel layer 211 is, for example, about 1 to 20 nm. By the insulating tunnel layer 211, it is possible to suppress a spin relaxation caused when electrons spin-polarized from the ferromagnetic electrode 14 are injected into the laser (W. H. Butler, et al., “Spin-dependent tunneling conductance of Fe|MgO|Fe sandwiches,” Physical Review B 63, 054416 (2001).). Al₂O₃ or the like may be used as the insulating tunnel layer 211 instead of MgO.

The lasing threshold of the circularly polarized light by the majority/minority carriers is a value calculated by equation (2) when the spin relaxation can be ignored. However, in an actual device, the spin of the current injected into the active layer is x times (0<x<1) due to relaxation with respect to the spin polarization of the ferromagnetic material. Therefore, the range of the current where lasing by the circularly polarized light in only one direction is Iₜₕ/(1+x|P|)<I<Iₜₕ/(1−x|P|), and the range of the current expected to have the effect of embodiments of the present invention is limited as compared with the case where spin relaxation can be ignored.

According to the laser module according to the present embodiment, since the spin relaxation of spin-polarized electrons can be suppressed, the limitation of the current range due to the spin relaxation can be suppressed, and driving can be performed, while suppressing the fluctuation of light intensity in a wider current range.

In the present embodiment, although an example in which the n-type electrode is a ferromagnetic electrode is shown, the p-type electrode may be a ferromagnetic electrode. In this case, the insulating tunnel layer is disposed between the ferromagnetic electrode (p-type electrode) and the p-type clad layer.

### Third Embodiment

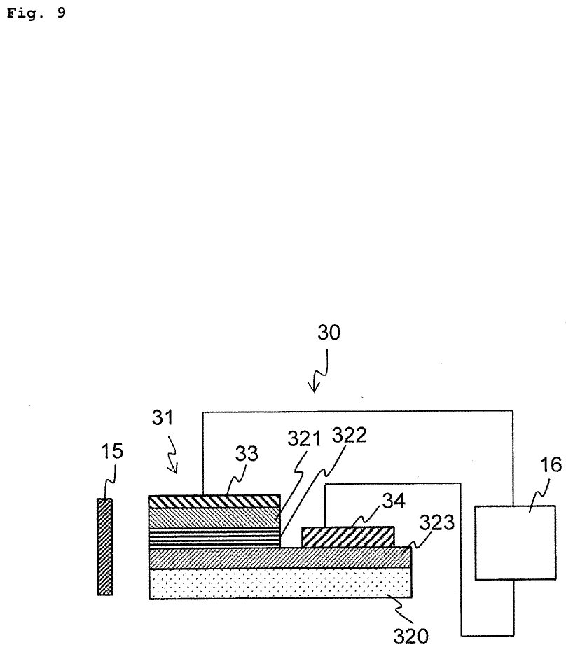

A laser module according to a third embodiment of the present invention will be described with reference to FIG. 9.

As shown in FIG. 9, a semiconductor laser 31 in a laser module 30 according to the present embodiment has a laminated structure including an n-type AlGaAs clad layer 323, a GaAs active layer 322, and a p-type AlGaAs clad layer 321 on a semi-insulating GaAs substrate 320, and includes a ferromagnetic electrode (n-type electrode) 34 on the side of the laminated structure on the n-type AlGaAs clad layer 323. A p-type electrode 33 is provided on the surface of the p-type AlGaAs clad layer 321.

In the semiconductor laser 31, spin-polarized electrons are injected into the active layer 322 from the ferromagnetic electrode (n-type electrode) 34 through the n-type AlGaAs clad layer 323. As a result, lasing is performed in the same manner as in the first embodiment, and the laser module 30 can obtain a good characteristic in which the fluctuation of the light intensity is very small.

The laser module according to the present embodiment has the same effect as that of the laser module according to the first embodiment.

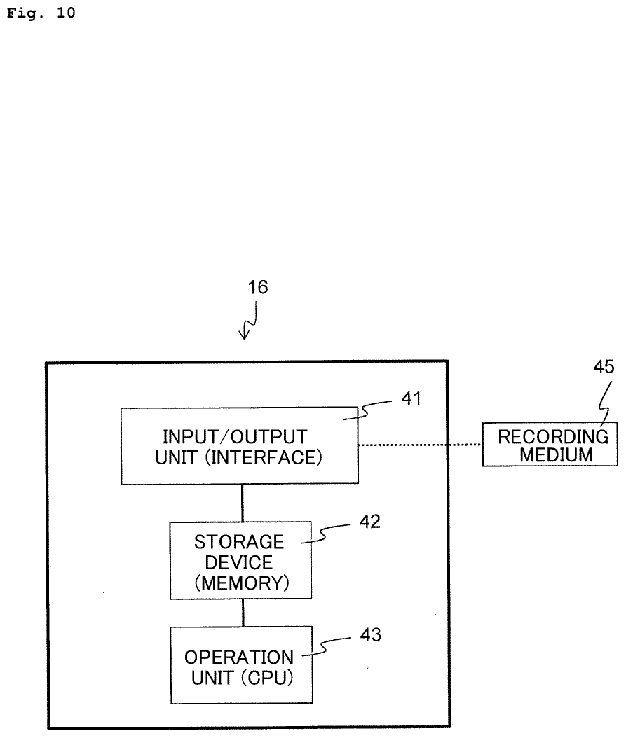

FIG. 10 shows an example of the configuration of a computer in the control device 16 of the laser module according to the embodiment of the present invention. The laser module control device 16 can be realized by a computer including a central processing unit (CPU) 43, a storage device (storage unit) 42, and an interface device 41, and a program that controls these hardware resources. Here, the semiconductor laser 11 is connected to the interface device 41. The CPU 43 executes the laser module control method according to the embodiment of the present invention according to the laser module control program stored in the storage device 42. In this way, the control program of the laser module causes the control device of the laser module to function.

The control device 16 of the laser module according to the embodiment of the present invention may include a computer inside the device, or may realize at least part of the computer's functions using an external computer. Also, the storage unit may also use a storage medium 45 that is external to the device, and a control program of the laser module stored in the storage medium 45 may be read and executed. Examples of the storage medium 45 include various magnetic recording media, a magneto-optic recording medium, a CD-ROM, a CD-R, and various memories. Also, the control program of the laser module may be supplied to the computer via a communication line such as the Internet.

Although an example in which the laser module according to the present embodiment of the present invention is applied to a GaAs-based laser is shown, it may be applied to an InP-based laser or the like.

In the embodiment of the present invention, an example of the structure, dimensions, materials, etc. of each component is shown in the laser module, the control method of the laser module, the configuration of the control device, etc., but the invention is not limited thereto. Any laser module may be used as long as it can exhibit the function of the laser module and exhibit the effect thereof.

### INDUSTRIAL APPLICABILITY

Embodiments of the present invention relates to a laser module and can be applied to an optical communication system.

### REFERENCE SIGNS LIST

1 Laser module
11 Semiconductor laser
15 Quarter-wave retarder

1-6. (canceled)

7. A method, comprising:
injecting a current into a semiconductor laser of a laser module, wherein the current is higher than a threshold current of a first one of a clockwise circularly polarized light or a counterclockwise circularly polarized light, wherein the current is lower than a threshold current of a second one of the clockwise circularly polarized light or the counterclockwise circularly polarized light, wherein the semiconductor laser is configured to oscillate with the clockwise circularly polarized light or the counterclockwise circularly polarized light, and wherein the laser module further comprises a quarter-wave retarder disposed on an emission surface side of the semiconductor laser.

8. A laser module comprising:
a semiconductor laser configured to oscillate with a clockwise circularly polarized light or counterclockwise circularly polarized light; and
a quarter-wave retarder disposed on an emission surface side of the semiconductor laser.

9. The laser module according to claim 8, wherein
the semiconductor laser is configured to be driven by a current which is higher than a threshold current of a first one of a clockwise circularly polarized light or a counterclockwise circularly polarized light, wherein the threshold current is lower than a threshold current of a second one of a clockwise circularly polarized light or a counterclockwise circularly polarized light.

10. The laser module according to claim 9, wherein the semiconductor laser includes:
an n-type clad layer;
an active layer;
a p-type clad layer;
an n-type electrode electrically connected to the n-type clad layer; and
a p-type electrode electrically connected to the p-type clad layer,
wherein the n-type clad layer, the active layer, and the p-type clad layer are arranged in this order, and
at least one of the n-type electrode or the p-type electrode is a ferromagnetic electrode made of a ferromagnetic material.

11. The laser module according to claim 10,
wherein the ferromagnetic electrode is magnetized in a direction parallel to a direction of emitted light of the semiconductor laser.

12. The laser module according to claim 11, wherein
the ferromagnetic electrode is the n-type electrode, and
the semiconductor laser further includes an insulating tunnel layer disposed between the n-type electrode and the n-type clad layer.

13. The laser module according to claim 11, wherein
the ferromagnetic electrode is the p-type electrode, and
the semiconductor laser further includes an insulating tunnel layer disposed between the p-type electrode and the p-type clad layer.

14. The laser module according to claim 10, wherein
the ferromagnetic electrode is the n-type electrode, and
the semiconductor laser further includes an insulating tunnel layer disposed between the n-type electrode and the n-type clad layer.

15. The laser module according to claim 10, wherein
the ferromagnetic electrode is the p-type electrode, and
the semiconductor laser further includes an insulating tunnel layer disposed between the p-type electrode and the p-type clad layer.

16. The laser module according to claim 8, wherein the semiconductor laser includes:
an n-type clad layer;
an active layer;
a p-type clad layer;
an n-type electrode electrically connected to the n-type clad layer; and
a p-type electrode electrically connected to the p-type clad layer;
wherein the n-type clad layer, the active layer, and the p-type clad layer are arranged in this order, and
the n-type electrode and the p-type electrode or a ferromagnetic electrode made of a ferromagnetic material.

17. The laser module according to claim 16,
wherein the ferromagnetic electrode is magnetized in a direction parallel to a direction of emitted light of the semiconductor laser.

18. The laser module according to claim 17, wherein
the ferromagnetic electrode is the n-type electrode, and
the semiconductor laser further includes an insulating tunnel layer disposed between the n-type electrode and the n-type clad layer.

19. The laser module according to claim 17, wherein
the ferromagnetic electrode is the p-type electrode, and
the semiconductor laser further includes an insulating tunnel layer disposed between the p-type electrode and the p-type clad layer.

20. The laser module according to claim 16, wherein
the ferromagnetic electrode is the n-type electrode, and
the semiconductor laser further includes an insulating tunnel layer disposed between the n-type electrode and the n-type clad layer.

21. The laser module according to claim 16, wherein
the ferromagnetic electrode is the p-type electrode, and
the semiconductor laser further includes an insulating tunnel layer disposed between the p-type electrode and the p-type clad layer.

22. A laser apparatus comprising:
semiconductor laser configured to oscillate with a clockwise circularly polarized light or a counterclockwise circularly polarized light;
a quarter-wave retarder disposed on an emission surface side of the semiconductor laser; and
a controller configured to inject into the semiconductor laser a current higher than a threshold current of a first one of a clockwise circularly polarized light or a counterclockwise circularly polarized light, wherein the threshold current is lower than a threshold current of a second one of a clockwise circularly polarized light or a counterclockwise circularly polarized light.

23. The laser apparatus of claim 22, wherein the first one is the clockwise circularly polarized light and the second one is the counterclockwise circularly polarized light.

24. The laser apparatus of claim 22, wherein the first one is the counterclockwise circularly polarized light and the second one is the clockwise circularly polarized light.
